(19) United States
(12) Patent Application Publication
(10) Pub. No.: US 2013/0294042 A1
(43) Pub. Date: Nov. 7, 2013

(54) METHODS AND APPARATUS FOR CONNECTING PLANAR POWER ELECTRONICS DEVICES

(71) Applicants: Guo-Quan LU, Blacksburg, VA (US); David Berry, Christiansburg, VA (US); Yunhui Mei, Tianjin (CN)

(72) Inventors: Guo-Quan LU, Blacksburg, VA (US); David Berry, Christiansburg, VA (US); Yunhui Mei, Tianjin (CN)

(21) Appl. No.: 13/889,017

(22) Filed: May 7, 2013

Related U.S. Application Data
(60) Provisional application No. 61/643,423, filed on May 7, 2012.

(51) Int. Cl. H01L 25/00

(52) U.S. Cl. CPC H01L 25/00
USPC 361/808

(57) ABSTRACT

The present disclosure teaches a power module that includes a chip, a first substrate, and one or more electrically conductive inserts disposed between the chip and the first substrate. The inserts can be corrugated metal sheets, metal tubes, metal wires, or metal rods. One or more of those inserts form a layer in the planar direction of a first interstitial space between the chip and the first substrate.

### FIELD OF THE INVENTION

The present invention generally relates to devices and methods for power semiconductor module packaging, particularly devices and methods for three dimensional power module packaging.

### BACKGROUND DESCRIPTION

Power electronics devices such as insulated-gate bipolar transistors (IGBT) are found in a wide range of applications, including inverters in electrical cars, wind-power generators, drivers on trains, and electric machines. The demand for high frequency, high power density, and more integrated power electronics devices requires advanced packaging technologies. Traditional two-dimensional packaging of power semiconductor devices makes it difficult to realize full integration of components such as gate driver, controller, passive components, and other sensors and communication circuitry. In addition, the long substrate tracks, and bonding wires contribute to parasitic inductance and resistance and increase the wire delay. Furthermore, the planar structure of two dimensional packaging frequently have high thermal stresses, which may result in chip failure such as flexing, cracking or broken joints.

Three dimensional power module packaging represents an improvement in packaging technologies. In three dimensional packaging, more than one layer of functional devices are packaged on top of each other. Each layer of packaging is a two dimensional structure, in which the substrate accommodates, for example, power chips, wirebond pads used to connect source and gate to the substrate, drain source, and gate tracks, and terminal leads connected to outside power bus. On top of this layer, in three dimensional packaging, there will be another substrate to accommodate additional layer of devices and chips. The technical challenges in three-dimensional packaging include 1) how different layers are bond together to form three dimensional packaging; 2) how to effectively manage heat dissipation of chips on each layer; and 3) how to alleviate thermal stress caused by uneven thermal expansions.

The current technology for interconnecting these chips inside power modules typically uses a lead or lead-free solder alloy, or conductive polymeric glue, such as an epoxy. These materials, however, have poor thermal properties and do not effectively dissipate heat generated by chips. They also have poor electrical properties and fail to effectively reduce loss of electrical power, and low mechanical strength and reliability. Furthermore, due to the low melting temperatures of solder alloys and low decomposition temperatures of epoxies, these materials may not be suitable for high temperature applications where SiC or GaN chips are used.

Therefore, it is desirable to find new methods and devices for power electronics packaging in order to meet the increasing demands for high power density and longevity for power modules.

### SUMMARY

The present disclosure teaches a power module that has one or more chips, one or more substrates, and one or more electrically conductive inserts disposed between a chip and a substrate. The inserts can be corrugated metal sheets, metal tubes, metal wires, or metal rods. One or more of those inserts form a layer in the planar direction of an interstitial space between the chip and the substrate.

Furthermore, the inserts are affixed in place by a bonding material that is chosen from solders, conductive epoxies, silver paste for low temperature sintering, and any materials suitable for transient liquid phase bonding.

The disclosure also teaches a method for connecting one or more chips to substrates, which include the steps of obtaining one or more metal inserts and affixing them between the substrate and the chip using a bonding material so that one or more inserts form a layer in an interstitial space between the substrate and the chip. Simulation results show that using the metal inserts in the packaging of the power module reduces the temperature of the power module by facilitating heat dissipation. It also reduces thermal stress in the power module.

### BRIEF DESCRIPTION OF DRAWINGS

These and other features, aspects and advantages of the present disclosure will become better understood when the following detailed description is read with reference to the accompanying drawings in which like characters represent like parts throughout the drawings, wherein:

FIG. 1 is a schematic diagram of one embodiment in this disclosure, in which one type of corrugated sheet is used as the insert.

FIG. 2 is a schematic diagram of another embodiment in which another type of corrugated sheet is used as the insert.

FIGS. 3A, 3B, and 3C illustrate embodiments using metal tubes as inserts.

FIGS. 4A, 4B, and 4C illustrate embodiments using solid rounds as inserts.

FIGS. 5A and 5B are diagrams illustrating an elliptical solid wire as the inserts.

FIGS. 6A and 6B compare temperature profiles of three different power electronics packaging configurations.

While the above-identified drawing figures set forth alternative embodiments, other embodiments of the present invention are also contemplated, as noted in the discussion. In all cases, this disclosure presents illustrated embodiments of the present invention by way of representation and not limitation. Numerous other modifications and embodiments can be devised by those skilled in the art which fall within the scope and spirit of the principles of this invention.

### DETAILED DESCRIPTIONS OF THE EMBODIMENTS

In one embodiment, a sterling silver tube (e.g., 1.6 mm O.D., 1.0 mm I.D.) was cut to length and pressed with a Carver Hot Press so that the cross section of the tube became oblong in shape. The cross section of the tube became elongated in one direction (i.e., the elongated direction) and shortened in the direction perpendicular to the elongated direction (i.e., the shortened direction). Assuming the diameter of the flattened tube in its elongated direction is D1 and that in its shorted direction is D2. D2 is larger than zero. The ratio of D1:D2 ranges from 100:1 to 1.5:1, preferably from 50:1 to 2:1, more preferably from 10.1 to 2:1. The flattened tubes were then etched for 1 minute in a 1:3 nitric acid solution.

A plurality of partially flattened tubes were sintered to a silver metallized substrate (i.e., the first substrate) with its elongated direction substantially parallel to the surface of the substrate using nanoTach® nanosilver paste provided by NBE Tech, LLC of Blacksburg, Va. The paste contains silver particles having a diameter of 500 nm or less or of 100 nm or less. The nano-sized silver particles are sintered at a temperature below 275° C. to bind the tubes to the substrate. After the chip or chips were attached to the first substrate, tubes were attached to the other side of the chip using the sintered nano-sized silver particles. In this case, the top terminal of the chip is attached to the flattened tubes. After the bonding process, the tubes were sandwiched between the top substrate and the chip. The resulting device is an operational two-sided module having an electrically conductive resilient interface capable of expansion and contraction.

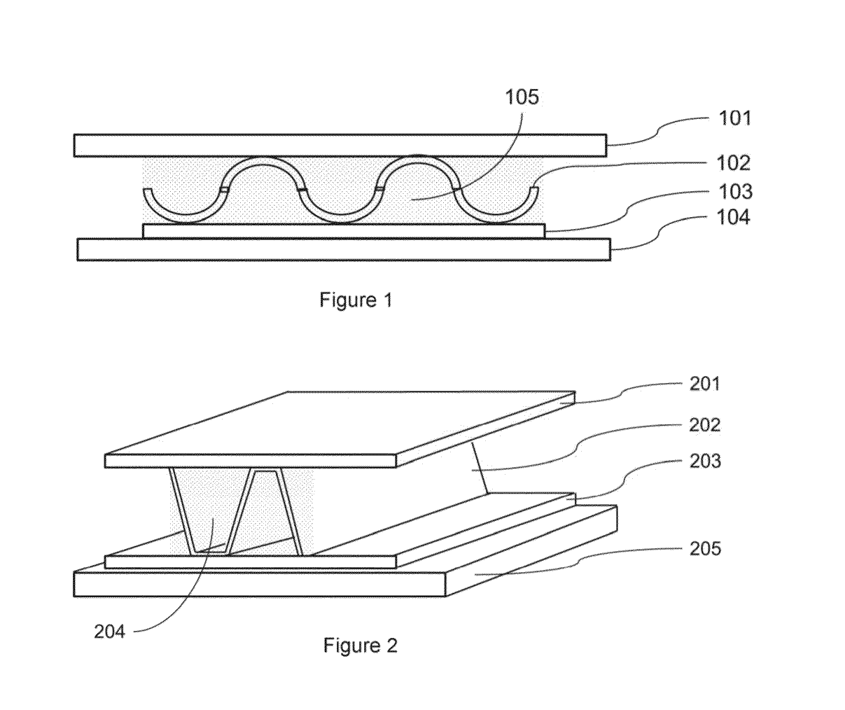

FIG. 1 is a schematic diagram for one embodiment of the current disclosure. In this embodiment, there is a substrate 101, a corrugated metal sheet 102 as an insert, a chip 103 mounted on substrate 104. The corrugated metal sheet 102 is patterned into folds or parallel undulating ridges and grooves having a contour curvilinear in its shape. The groove period is p and the groove height is h, while p and h can be adjusted by using pressing fixtures. The spacing period p of grooves can be symmetric. It can also be asymmetric to maximize contact area between the metal sheet 102 and the chip 103. As shown in FIG. 1, one side of the corrugated metal sheet 102 is attached to the substrate 101 and the other side of the corrugated metal sheet is attached to the chip 103.

In the embodiment depicted in FIG. 1, the space between undulating ridges and the substrate, and the space between undulating grooves and the chip are filled with a thermally conductive encapsulation material 105. In addition to providing a seal to the chip, the encapsulation material 105 also facilitates heat dissipation and reduces thermal stress created by uneven heat distribution.

Referring to FIG. 2, in another embodiment of the current disclosure, there is a substrate 201, a corrugated metal sheet 202 as the insert, and a chip 203 attached to a bottom substrate 205. Different from the corrugated metal sheet 102 in FIG. 1, the cross section of the corrugated metal sheet 202 has undulating straight sections. Likewise, various spaces between the substrate 201, the metal sheet 202, and the chip 203 are filled with a thermally conductive encapsulation material 204.

In a further embodiment, the flat portion at the convex curve is increased to form repeating parallelograms, the thickness of the sheet or foil is t, the period of the pattern is p, and the groove height is h, t, p, and h can be changed to accommodate various devices. The spacing period p of grooves is asymmetric to maximize surface area.

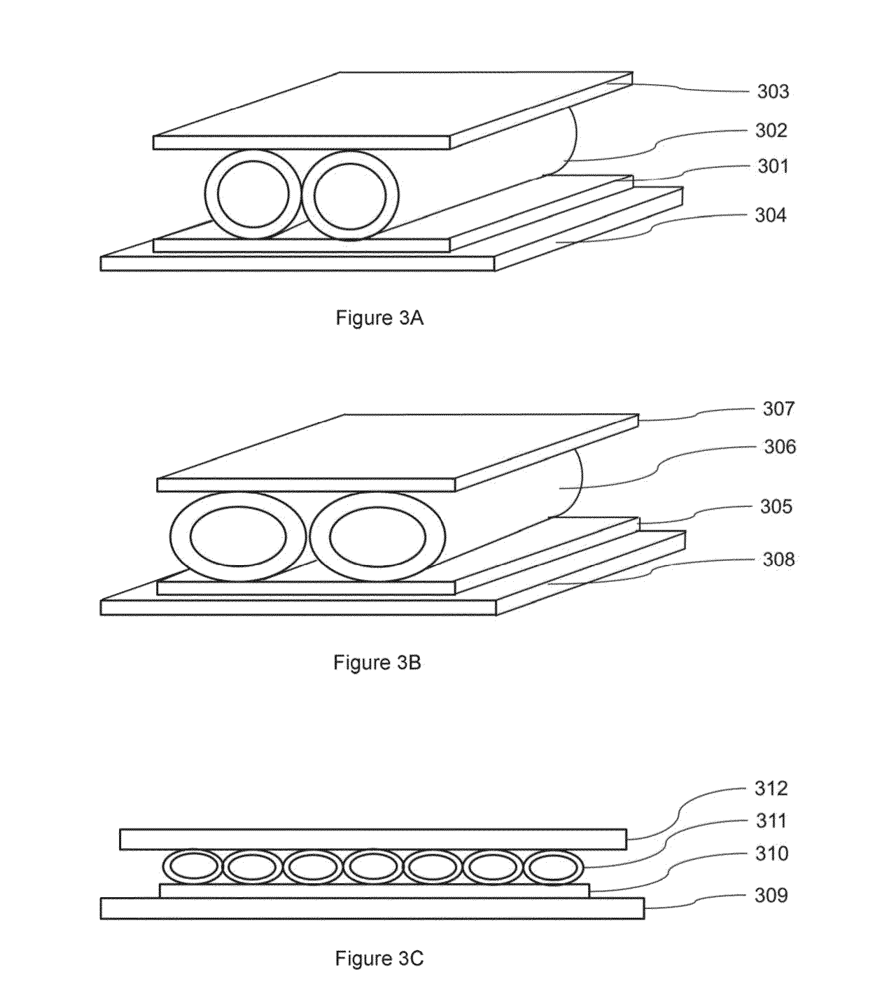

Referring to FIG. 3A, another embodiment of the current disclosure includes a substrate 304, a chip 301, a plurality of metal tubes 302 as the inserts, and a top substrate 303. The tubes 302 are attached to the chip 301 and the top substrate 303 using a bonding material. The chip is also attached to substrate 304 using the bonding material. The period is p, the height is h, the length is l, the inner diameter of the tubes 302 is ID1, and the outer diameter is OD1. The cross section of the tubes is circular in shape.

FIG. 3B shows another embodiment of the current disclosure. In this embodiment, there is a top substrate 307, a plurality of deformed metal tubes 306, a chip 305 and a substrate 308. The tubes are pressed using a fixture and hydraulic press (such as a Carver press) so that the cross sections become elliptical, elongated in one direction and shortened in the direction perpendicular to the elongated direction. The period is p, the height is h, the length is l, the inner diameter of the tubes 306 in the elongated direction is ID_{L}, and the outer diameter of the tubes 306 in the elongated direction is OD_{L}, the inner diameter of the tubes 306 in the shortened direction is ID_{S}, and the outer diameter of the tubes 306 in the shortened direction is ODS. ID_{L}:ID_{S}≈OD_{L}:OD_{S}, they both range from 100:1 to 1.5:1, the preferred range is from 50:1 to 2:1, the most preferred range is from 10:1 to 2:1.

FIG. 3C shows a variation of the embodiment depicted in FIG. 3B. In this case, a plurality of partially flatten metal tubes 311 are used as inserts between a substrate assembly 312 and a chip 310 mounted on substrate 309.

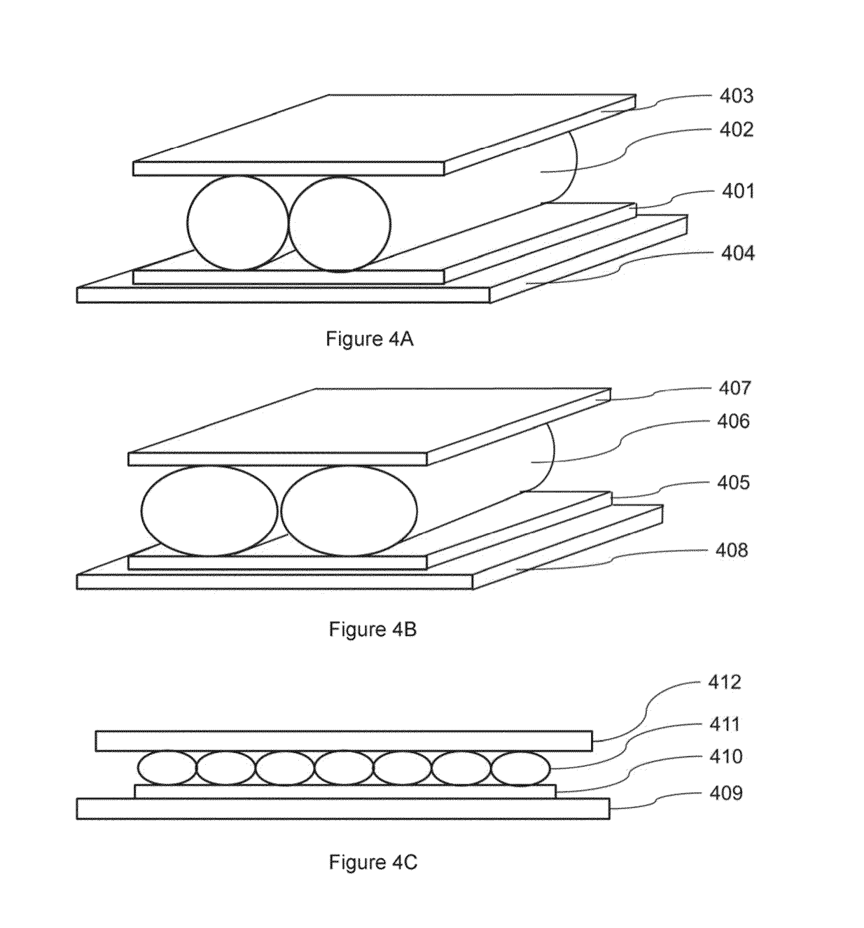

Referring to FIG. 4A, in still another embodiment of the current disclosure, there is a substrate 404, a chip 401, a plurality of solid metal rounds 402, and a top substrate 403. The solid rounds 402 are attached to the substrate 404 and the chip 401 using a bonding material. Substrate 403 is also attached to solid metal rounds 402 using the bonding material. The period is p, the height is h, the length is l, the diameter of the solid round 402 is D1. The solid metal rounds can be metal rods or metal wires. FIG. 4B shows a variation of the embodiment in FIG. 4A, in which the solid rounds 406 are compressed to form an elliptical cross section. The partially flattened solid rounds 406 are attached between a substrate 407 and a chip 405. The period is p, the height is h, the length is l, the diameter of the solid rounds 406 in the elongated direction is D_{L}, the diameter of the solid rounds 402 in the shortened direction is D_{S}. The ratio D_{L}:D_{S} ranges from 100:1 to 1.5:1, the preferred range is from 50:1 to 2:1, the most preferred range is from 10:1 to 2:1. FIG. 4C shows an array of partially flattened solid rounds 411 affixed between a top substrate 412, a chip 410 mounted on the substrate 409.

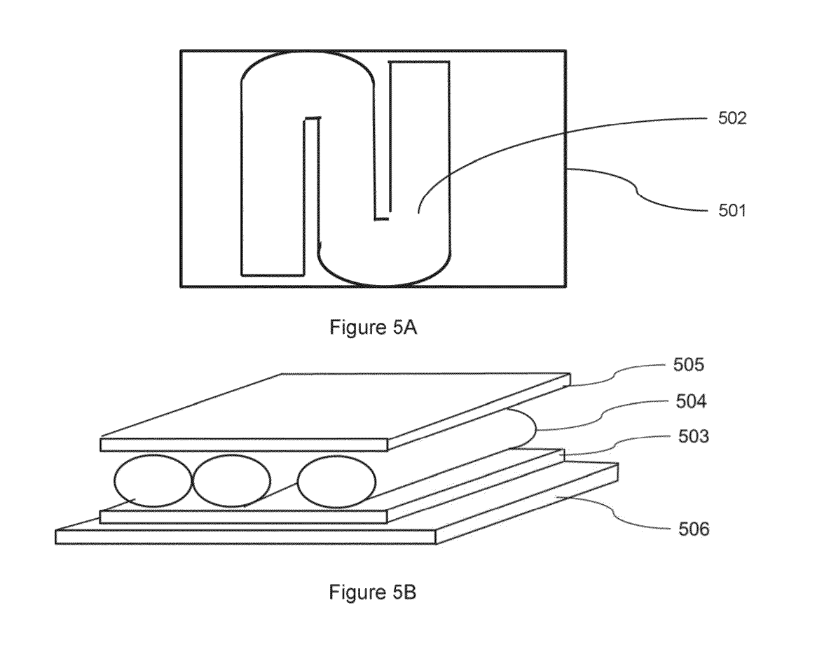

Solid wires or rods can be bent into various two dimensional structures such as coils, and various serpentine shapes. They can be used as inserts. FIG. 5A illustrates an elliptical solid bent 502 as the insert or as a part of a larger serpentine-shaped insert, which is affixed to the chip 501. FIG. 5B is another view of the embodiment shown in FIG. 5A, wherein the solid bent 502 is affixed between a top substrate 505 and a chip 503.

The solid round can be partially flattened using a fixture and hydraulic press to become elliptical, elongated in one direction (the elongated direction) and shortened in the direction perpendicular to the elongated direction (the shortened direction). The period of corrugation can be adjusted to accommodate surface connection pads and to avoid surface features. The space between the solid bent and substrate, the space between the solid bent and the chip can all be filled with thermally conductive encapsulation material to facilitate heat dissipation and to reduce thermal stress created by uneven heat distribution.

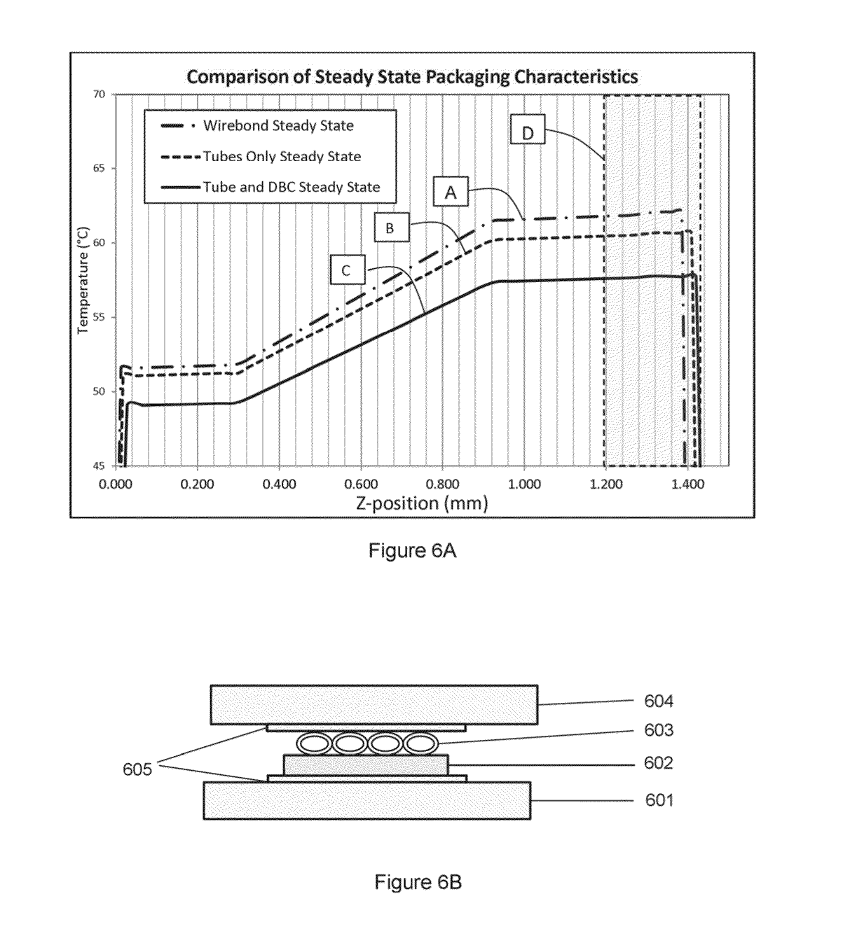

FIG. 6A shows computer simulation results of temperature profiles for three different packaging configurations under steady state. FIG. 6B is a schematic illustration of the configuration corresponding to line C. In this configuration, a chip 602 is attached to a substrate 601 using sintered nano-sized silver particle bonding material 605. A plurality of metal tube inserts 603 are attached to the top of the chip 602. A second substrate 604 is attached to the top of the tube inserts 603 using sintered nano-sized silver particle bonding material 605. The origin (i.e., Z=0) in FIG. 6A correponds to the bottom of the substrate 601. The horizontal axis represents locations in the vertical direction in the device of FIG. 6B. The region surrounded by line D indicates the location of the chip in FIG. 6B. The vertical axis shows the temperature. The boundary conditions for the simulation results (line A, line B, and line C) shown in FIG. 6A include a 100 W chip as the heat source, a heat sink of 10,000 W/m² attached to the bottom substrate 601, the rest of device is air cooled and has a convection heat flux of 100 W/m².

Line C in FIG. 6A corresponds to the configuration depicted in FIG. 6B, which has a substrate 604 attached to the metal tubes 603. Line B corresponds to a configuration equivalent to the device in FIG. 6B without the substrate 604, i.e., the metal tube inserts 603 are exposed to the air. Line A in FIG. 6A corresponds to a configuration equivalent to the device in FIG. 6B except that it does not have substrate 604 while wirebond instead of metal tube inserts are used. Therefore, in the configuration corresponding to line A, wirebond is exposed to the air.

As one can see, under steady state, the temperature of the substrate assembly 601 rises as it gets closer to the chip region. However, the configuration shown in FIG. 6B has the smallest rise in temperature among the three and therefore the smallest thermal stress. Also, when metal tube inserts are used, the temperature rises in the device is lower than when wirebond is used, indicating that metal tube inserts are more effective in dissipating heat generated in the chip region.

TABLE 1

| | | | Chip stress (one layer of | |
|---|---|---|---|---|
| | | Chip stress (packaged | tube inserts between | |
| | | with top substrate- | the chip and the | Stress |
| | Thermal Conditions | without insert layer) | substrate) | reduction |
| A. | Initial 290° C. lowered to | 1100 MPa | 493 MPa | 44.8% |
| | 25° C. | | | |
| B. | Initial 25° C. increased to | 957 MPa | 402 MPa | 42% |
| | 250° C. | | | |
| C. | Initial 290° C. lowered to | 931 MPa | 381 MPa | 41% |
| | 25° C. and heated back to | | | |
| | 250° C. | | | |

Table 1 compares computer simulation results of Von Mises stresses for packages with and without the inserts. It shows significant reduction in CTE (coefficient of thermal expansion) stress in each of the three thermal conditions when a layer of metal tube inserts is placed between the chip and the substrate on the topside of the chip (i.e., emitter side). The range of height h (e.g., referring to FIGS. 2, 3, and 4) is from 0.254 mm to 2.54 mm. Thermal condition A assumes that the device is fabricated at 290° C. (and free of stress at 290° C.) and then the temperature is lowered to 25° C. In that case, the chip stress is 1100 MPa when packaged with top substrate without an insert but is lowered to 493 MPa when a layer of metal tubes is inserted between the chip and the top substrate. The stress reduction is 44.8% by including metal tube inserts in the packaging.

Under thermal condition B, the package starts at room temperature 25° C. where it is stress free. Then the package temperature is increased to 250° C. In this case, the chip stress without insert is 957 MPa while the chip stress with insert is 402 MPa. The stress reduction is 42%.

Under thermal condition C, the package is fabricated at 290° C., then its temperature is lowered to room temperature 25° C. The package is then heated 25° C. to 250° C. In this case, the chip stress without insert is 931 MPa while the chip stress with insert is 381 MPa. The stress reduction is 41%.

The insert is made of an electrically conductive metal such as aluminum, copper, silver, gold or combinations thereof whether by electrical or chemical coating or alloying. In one embodiment, there is more than one layers of the inserts made of electrically conductive metal stacked on the top of each other.

The encapsulation material is used to fill the voids between substrates, as well as between substrate and chip. Such encapsulation material is a thermally conductive encapsulation material to facilitate heat dissipation and to reduce thermal stress created by uneven heat distribution. Examples of such material include: silicone, flexibilized epoxy, thermosetting polymer, flouropolymer, thermoplastic polymer, polyimide, polymer or metal foams and combinations or composites thereof.

The bonding material can be solders, conductive epoxy materials, materials suitable for transient liquid phase bonding, or any bonding materials suitable for low temperature joining technologies. One example of the bonding material is a paste comprising fine metal or metal alloy particles. In one embodiment, the size of metal and metal alloy particles is on the order of 500 nm or less, and or on the order of 100 nm or less (e.g., 1-100 nm). Such nanoparticle bonding material can form densified metallic interconnections by sintering at relatively low temperatures with reduced or no pressure application being required. The materials can be applied and processed like a solder paste or epoxy (e.g., dispensing, stencil/screen printing, etc.). One example of such a bonding material is NanoTach® made by NBE Technologies, LLC in Blacksburg, Va., which contains nano-sized particle of silver. Other metals (e.g., copper) or metal alloys may also be used. Processing conditions that allow for low temperature processing over short time periods also exist. These processing conditions include both a drying and a sintering step, during each of which the temperature is rapidly ramped up. Effective bonding can be achieved at lower temperature without the need for extended processing times.

Such variations are within the scope of this disclosure. It is to be understood that the disclosure is not to be limited to the specific embodiments disclosed, and that the modifications and embodiments are intended to be included within the scope of the dependent claims.

What is claimed is:

1. A power module comprising:
a chip;
a first substrate; and
one or more electrically conductive inserts disposed between the chip and the first substrate, wherein said one or more inserts form a layer in a planar direction of a first interstitial space between the chip and the first substrate.

2. The power module of claim 1, further comprising a second substrate, wherein the second substrate is disposed on the opposite side of the chip from the first substrate and one or more inserts form a layer in a planar direction of a second interstitial space between the chip and the second substrate.

3. The power module of claim 1, wherein the insert is a corrugated metal sheet.

4. The power module of claim 1, wherein the insert is a metal tube, metal wire, or metal rod.

5. The power module of claim 4, wherein a plurality of inserts are adapted to form a layer in the planar direction of the interstitial space between the chip and the substrate.

6. The power module of claim 4, wherein the insert has a serpentine shape.

7. The power module of claim 1, wherein the insert is compressed between the chip and the substrate.

8. The power module of claim 1, wherein the insert is made of a material chosen from aluminum, copper, silver, gold, or combinations thereof.

9. The power module of claim 1, wherein the insert is affixed in place using a bonding material.

10. The power module of claim 9, wherein the bonding material is chosen from solders, epoxy materials, bonding materials suitable for transient liquid bonding, or bonding materials comprising fine particles of metals or metal alloys.

11. The power module of claim 10, wherein the bonding material comprises nano-sized silver particles.

12. The power module of claim 1, further comprising an encapsulation material, wherein the encapsulation material is selected from the group consisting of silicone, flexibilized epoxy, thermosetting polymer, flouropolymer, thermoplastic polymer, polyimide, polymer or metal foams and combinations or composites thereof.

13. The power module of claim 1, wherein a plurality of inserts form more than one layers disposed in the interstitial space between the chip and the substrate.

14. A method for connecting a chip and a substrate, comprising:
obtaining one or more metal inserts; and
affixing said one or more inserts between the substrate and the chip using a bonding material so that one or more inserts form a layer in an interstitial space between the substrate and the chip.

15. The method of claim 14, further comprising:
applying an encapsulation material between the substrate and the chip.

16. The method of claim 11, wherein the insert is chosen from a corrugated metal sheet, a metal tube, a metal wire, or a metal rod.

17. The method of claim 14, wherein the layer comprises a plurality of metal wires, metal tubes, metal rods, or a combination thereof.

18. The method of claim 17, wherein the layer is a corrugated metal sheet.

19. The method of claim 14, wherein more than one layer of inserts are disposed in the interstitial space between the chip and the substrate.

20. The method of claim 14, wherein inserts is attached to the substrate by sintered silver.
